(19) United States
(12) Patent Application Publication
(10) Pub. No.: US 2012/0242399 A1
(43) Pub. Date: Sep. 27, 2012

(54) MOBILE TERMINAL AND METHOD OF WRITING PROTECTION FOR MEMORY CARD IN THE MOBILE TERMINAL

(75) Inventor: Yinong LIU, Beijing (CN)

(73) Assignee: SONY ERICSSON MOBILE COMMUNICATIONS AB, Lund (SE)

(21) Appl. No.: 13/428,153

(22) Filed: Mar. 23, 2012

(30) Foreign Application Priority Data
Mar. 25, 2011 (CN) 201110074366.X

(51) Int. Cl. H03K 17/945

(52) U.S. Cl. 327/517

(57) ABSTRACT

A mobile terminal and a method of writing protection for a memory card in the mobile terminal, the mobile terminal comprising a body, battery, and battery cover, at least part of the battery cover made of conductive material; the body comprising: a memory card socket configured to accommodate a pluggable memory card; at least one sensing member on a surface or internal of the body and spaced from the battery cover, and configured to face the part made of conductive material when the battery cover is closed; a capacitance sensor connected to the at least one sensing member and configured to sense capacitance between the sensing member and battery cover; and a write control unit configured to determine whether the battery cover is removed according to capacitance sensed by the capacitance sensor, and prohibit data being written into the memory card when the battery cover is removed.

### TECHNICAL FIELD

The present invention relates to the field of electronic technology, and particularly, to a mobile terminal and a method of writing protection for a memory card in the mobile terminal.

### DESCRIPTION OF THE RELATED ART

A smart phone with an independent operating system, used like a personal computer, can support the user to self-install programs such as software and games provided by a third party service provider, and can continually extend the functions of the smartphone through such programs. Thus, the smartphone becomes more and more popular. Since various software may be self-installed by the user, the inherent memory of the phone often cannot meet the demand on the memory space. Thus, the smart phone is usually provided with a memory card socket, so as to expand the memory space of the smart phone by inserting a pluggable memory card into the memory card socket. Thus the pluggable memory card is of vital importance to the smart phone. In the current market, conventional memory cards for the smart phone, for example, include Multimedia Card (MMC), Secure Digital Memory Card (SD card) , TransFlash (TF) card, etc., in which the SD card includes standard SD card, Elite Pro high speed card, miniSD card (also called as uSD card) and ultra speed SD card, etc.

In the operating system versions (e.g., Android 2.2 and above) of some smart phones, the application programs of the internal flash can be written into the pluggable memory card. If the memory card is pulled out during a process of writing the programs thereinto, at least part of the data will not be successfully written into the memory card during the above process. Thus, a data loss may be caused and the memory card may be unusable, i.e., the memory card has a risk of being damaged, and the return rate of the memory card is increased.

### SUMMARY OF THE INVENTION

The present invention is proposed with respect to the above problem in the prior art. The present invention is related to a mobile terminal and a method of writing protection for a memory card in the mobile terminal capable of stopping writing data into the memory card in time when the memory card is pulled out, so as to effectively provide a protection of the writing operation on the memory card.

According to an aspect of the present invention, a mobile terminal is provided, comprising a body, a battery and a battery cover; at least a part of the battery cover is made of conductive material; the body comprising: a memory card socket configured to accommodate a pluggable memory card; at least one sensing member provided on a surface or internal of the body and spaced apart from the battery cover, and configured to face the part made of conductive material when the battery cover is in a closed state; a capacitance sensor connected to the at least one sensing member and configured to sense capacitance between the sensing member and the battery cover; and a write is control unit configured to determine whether the battery cover is removed according to the capacitance sensed by the capacitance sensor, and prohibit data being written into the memory card when it is determined that the battery cover is removed.

According to another aspect, the write control unit is configured to determine that the battery cover is removed when the capacitance currently sensed by the capacitance sensor is smaller than a predetermined threshold; or the write control unit is configured to determine that the battery cover is removed when a decrement of the capacitance currently sensed by the capacitance sensor in relation to a previously sensed capacitance is larger than a predetermined threshold.

According to another aspect, the write control unit is further configured to allow data to be written into the memory card when it is determined that the battery cover is not removed.

According to another aspect, the sensing member is a metal sheet formed on the surface or internal of the body through metal insert molding.

According to another aspect, the at least one sensing member is spaced apart from the battery cover via air or a medium layer coated on a surface of the at least one sensing member, when the at least one sensing member is provided on the surface of the body.

According to another aspect, the part made of conductive material is grounded.

According to another aspect of the present invention, a method of writing protection for a memory card in a mobile terminal is provided, wherein the method comprising: a capacitance sensing step: sensing capacitance between a sensing member provided in the mobile terminal and a conductive part of a battery cover of the mobile terminal; a determining step: determining whether the battery cover is removed according to the capacitance sensed in the capacitance sensing step; and a writing protection step: prohibiting data being written into a pluggable memory card of the mobile terminal when the determining step determines that the battery cover is removed.

According to another aspect, allowing data to be written into the memory card when the determining step determines that the battery cover is not removed from the mobile terminal.

According to another aspect, determining that the battery cover is removed when the capacitance currently sensed in the capacitance sensing step is smaller than a predetermined threshold; or determining that the battery cover is removed when a decrement of the capacitance currently sensed in the capacitance sensing step in relation to a previously sensed capacitance is larger than a predetermined threshold.

According to various aspects of the present invention, by sensing whether the battery cover is opened, a writing protection can be effectively provided to the pluggable memory card when the battery cover is opened. Thus the damage of the memory card and the non-operation of the application program caused by the data writing error can be prevented, the data writing security of the memory card is improved, and the return rate of the memory card is effectively reduced.

Features described and/or illustrated with respect to one embodiment can be used in one or more other embodiments in a same or similar way, and/or combine with or replace features in other embodiments.

To be noted, the term “include/comprise/have” herein refers to existence of feature, component, step and assembly, not excluding existence or addition of one or more other features, components, steps, assemblies or a combination thereof.

Many aspects of the present invention can be understood better with reference to the following drawings. The constituent parts of the drawings are not necessarily drafted in proportion or to scale, but are presented just for illustrating the present invention more clearly. For the convenience of illustrating and describing some parts of the present invention, and promoting the understanding of the embodiments, some parts of the drawings may be enlarged, e.g., enlarging those parts with respect to other parts in an exemplary apparatus practically manufactured according to the present invention. Elements and features described in a drawing or embodiment of the present invention can be combined with elements and features illustrated in one or more other drawings or embodiments. In addition, same or corresponding reference signs are used to represent same or corresponding constituent parts in all the drawings, and they also can be used to represent same or corresponding constituent parts in more than one of the embodiments.

### BRIEF DESCRIPTION OF THE DRAWINGS

The accompanying drawings constitute a part of the specification, illustrate the embodiments of the present invention and together with the description serve to explain the present invention. The drawings described as follows illustrate several exemplary embodiments of the present invention, and a person skilled in the art can obtain other drawings based on these drawings without paying any creative effort. In the drawings:

FIG. 1 is an exploded diagram of a structure of a mobile terminal according to an embodiment of the present invention;

FIG. 2 is an exploded diagram of a structure of a mobile terminal according to another embodiment of the present invention;

FIGS. 3-4 are schematic diagrams of a battery cover sensing according to an embodiment of the present invention;

FIG. 5 is a schematic diagram of a battery cover sensing according to another embodiment of the present invention;

FIGS. 6-7 are schematic diagrams of a battery cover sensing according to another embodiment of the present invention;

FIG. 8 is a schematic block diagram of a mobile phone according to an embodiment of the present invention; and

FIG. 9 is a flowchart of a writing protection for a memory card according to an embodiment of the present invention.

### DETAILED DESCRIPTION OF THE PREFERRED EMBODIMENTS

These and further aspects and features of the present invention will be apparent with reference to the following description and attached drawings. In the description and drawings, particular embodiments of the invention have been disclosed in detail as being indicative of some of the ways in which the principles of the invention may be employed, but it is understood that the invention is not limited correspondingly in scope. Rather, the invention includes all changes, modifications and equivalents coming within the spirit and terms of the appended claims.

To be noted, in order to avoid the present invention from being vague due to unnecessary details, the drawings only illustrate device structure and/or processing step closely associated with the solution of the present invention, and other details not so necessary to understand the present invention are omitted.

In some mobile terminal designs, a card socket for accommodating a pluggable memory card is physically provided at a position on the body of the mobile terminal under a battery cover. Thus, the battery cover shall be removed before the memory card is inserted or pulled out. For such mobile terminal design, the present invention determines whether the memory card has a risk of being pulled out by sensing whether the battery cover is opened (i.e., removed). If the battery cover is not opened, the memory card will not be pulled out, and a program and/or other data can be safely written into the memory card. If the battery cover is opened, the memory card has a risk of being pulled out and the program and other data will be prohibited from being written into the memory card, so as to realize a writing protection of the memory card in the mobile terminal. In the embodiment of the present invention, the memory card may be MMC card, SD card, various memory sticks or any other type of pluggable memory card that can be used in the mobile terminal. In addition, the memory card may also be a Subscriber Identity Module (SIM) card.

In some mobile phone designs, in order that the mobile phone is thinner, the battery cover of the mobile phone is usually a metal battery cover made of a metallic material. The card socket for the pluggable memory card is usually disposed under the metal battery cover. Herein a mobile phone having a metal battery cover will be taken as an example to describe in more detail the solution of the present invention that protects the memory card. It shall be appreciated that the present invention is applicable to not only a mobile phone, but also a PDA and other mobile terminal using a memory card as long as the metal battery cover of such mobile terminal needs to be opened before the memory card is inserted or pulled out.

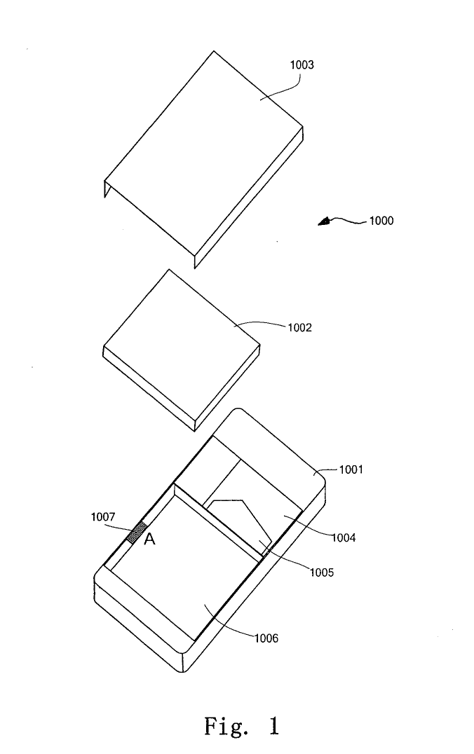

In an embodiment of the present invention, it is determined whether a metal battery cover is opened (i.e., removed) by sensing a capacitance change caused by a change of the position of the metal battery cover using a capacitance sensor. In this embodiment, as illustrated in FIG. 1, the mobile phone 1000 includes a body 1001, a battery 1002 and a battery cover 1003. The body 1001 for example may include conventional components such as a housing, a circuit mainboard, an input unit (e.g., keypad or touch screen) and a display, and may be further provided with a memory card socket 1004 for accommodating a pluggable memory card 1005. The battery cover 1003 is preferably a metal battery cover made of metallic or alloy material. When the metal battery cover is engaged with the body, i.e., being in a closed state, it is usually grounded through a grounding structure that is provided on the housing and connected to the circuit mainboard, for the purpose of Electro-Static Discharge (ESD) and ensuring the RF performance of the antenna of the mobile phone. In another embodiment, the battery cover 1003 may also be made of other conductive material (e.g., but not limited to, nonmetal conductive material such as carbon fiber).

In an embodiment of the present invention, in order to sense whether the conductive battery cover made of a conductive material is opened and to prevent data from being written into the memory card when the battery cover is opened, the body 1001 is further provided with a sensing member 1007, and, as is shown in FIG. 3, for example, a capacitance sensor 1009 and a write control unit 1010. As illustrated in FIG. 1, the sensing member 1007 is disposed on an inner surface of the sidewall (e.g., the sidewall of a battery accommodating portion 1006) of the body 1001. The position where the sensing member 1007 is disposed is represented as A in FIG. 1. When the battery cover is in the closed state, the sidewall of the battery cover overlaps with the sidewall (e.g., the sidewall of the battery accommodating portion 1006) of the body, so that the sensing member faces the sidewall of the battery cover and is spaced apart from the battery cover for a predetermined distance (e.g., the thickness of the sidewall of the body) by a sidewall of the body. Preferably, the sensing member may be a metal sheet (not limited thereto, e.g., other shapes being also possible) formed on the inner surface of the body 1001 through metal insert molding. In another embodiment of the present invention, the sensing member 1007 may be disposed inside the sidewall of the body 1001 through metal insert molding technology. In that case, when the battery cover is in the closed state, the distance between the battery cover and the sensing member will be smaller than a thickness of the sidewall of the body.

The capacitance sensor 1009 is connected to the sensing member 1007, so as to sense a capacitance between the sensing member 1007 and the battery cover 1003. In an embodiment of the present invention, the capacitance sensor 1009 takes the sensing member 1007 as one plate of the capacitor and the battery cover 1003 as the other plate of the capacitor. According to the principle that the capacitance is in inverse proportion to the distance between the plates, that is to say, when the battery cover approaches the sensing member, the capacitance therebetween will be increased, and when the battery cover moves away from the sensing member, the capacitance will be decreased. Thus, in the embodiment of the present invention, when the battery cover is mounted on the body, the distance between the sensing member and the battery cover is the minimum, and the capacitance therebetween is the maximum. When the battery cover is removed from the body, the capacitance between the sensing member and the battery cover is sharply decreased since the distance therebetween is sharply increased. Whether the battery cover is opened, i.e., whether it is removed from the body can be sensed according to such capacitance change between the sensing member and the battery cover.

Therefore, in the embodiment of the present invention, the write control unit 1010 determines whether the battery cover is removed according to the capacitance sensed by the capacitance sensor 1009, and prohibits (including stopping) data being written into the memory card when it is determined that the battery cover is removed. In detail, the write control unit 1010 may determine whether the battery cover is opened according to the magnitude or variation of the capacitance sensed by the capacitance sensor. For example, the write control unit 1010 may determine that the battery cover is opened when the capacitance sensed by the capacitance sensor is smaller than a predetermined first threshold, or when a variation (decrement) of the capacitance currently sensed by the capacitance sensor in relation to a previously sensed capacitance is larger than a predetermined second threshold, so as to prohibit data being written into the memory card. The first threshold may be reasonably determined according to the size of the conductive part of the battery cover, the size of the sensing member and/or the distance between the battery cover and the sensing member. The second threshold may be reasonably determined according to the time interval for the capacitance sensor to perform capacitance sensing, the first threshold and/or the capacitance when the battery cover is closed, but not limited thereto. The write control unit 1010 may allow data to be written into the memory card when it is determined that the battery cover is not removed according to the magnitude or variation of the capacitance sensed by the capacitance sensor.

In an embodiment of the present invention, the capacitance sensor 1009 and the write control unit 1010 for example may be disposed in the circuit mainboard (e.g., the printed circuit board) of the mobile phone.

FIG. 3 illustrates a schematic diagram of a metal battery cover sensing circuit when the sensing member 1007 is provided on the sidewall of the body according to an embodiment of the present invention. As illustrated in FIG. 3, the metal battery cover 1003 is grounded via a grounding structure 1011. The sensing member 1007 is provided on an inner side (see position A in FIG. 1) of the sidewall 1008 of the mobile phone body. When being closed, the battery cover 1003 covers the battery 1002, and the sidewall of the battery cover overlaps with the sidewall 1008 of the mobile phone body. In that case, the sensing member 1007 faces the sidewall of the battery cover and spaced apart from the battery cover. The capacitance sensor 1009 is connected to the sensing member 1007 via a contact 1012 (e.g., pogo pins or spring fingers). The write control unit 1010 may be connected to the capacitance sensor 1009 directly or indirectly, so as to prohibit or allow data to be written into the pluggable memory card according to the sensing result of the capacitance sensor, i.e., to disable or enable the writing operation on the memory card. When the metal battery cover is closed, the sidewall of the battery cover is very close to the sensing member 1007 (they are only separated by the sidewall of the housing of the mobile phone), and at that time, the capacitance sensor can sense a large capacitance from the sensing member 1007. When the metal battery cover is removed for a certain distance, as illustrated in FIG. 4, since the distance between the battery cover and the sensing member is increased, the capacitance sensed by the capacitance sensor from the sensing member is obviously decreased and gets smaller than a certain predetermined threshold, thus it can be determined that the battery cover is removed.

FIGS. 3-4 are only used to explain the principle for implementing an embodiment of the present invention, instead of limiting the shapes and positions of the illustrated components. In the actual design, the capacitance sensor 1009 and the write control unit 1010 may be not under the battery, but at any other appropriate position in the mobile phone body. The write control unit 1010 also may be integrated into the CPU of the mobile phone.

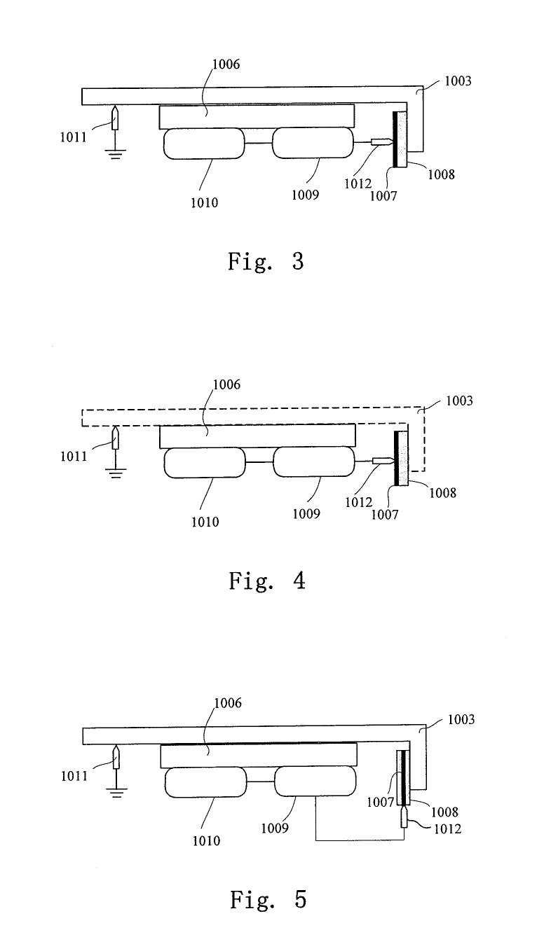

FIGS. 3-4 only illustrate the case where the sensing member 1007 is provided on the inner surface of the sidewall of the body. Alternatively, the sensing member 1007 may be provided inside the sidewall of the body, as illustrated in FIG. 5, and in that case, whether the battery cover is opened can also be sensed by sensing the capacitance variation caused when the battery cover moves.

With the above structure of the mobile phone, whether the battery cover is opened can be sensed, and a writing protection can be effectively provided to the pluggable memory card when the battery cover is opened. Thus, damage of the memory card and the failure in running of the application program caused by the data writing error can be prevented, the data writing security of the memory card is improved, and the return rate of the memory card is effectively reduced.

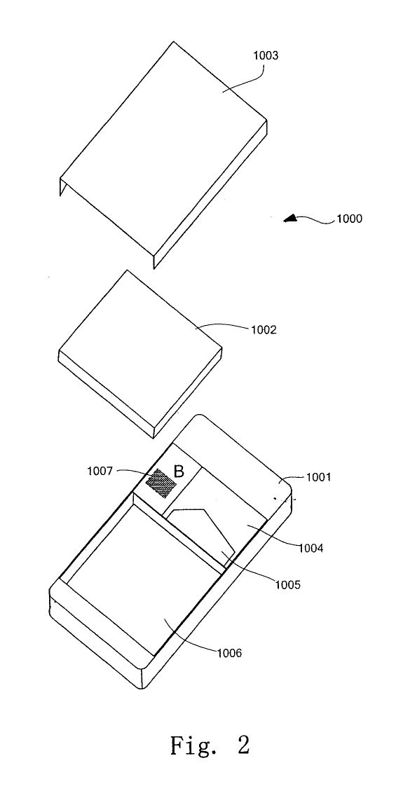

In the above structure of the mobile phone, the sensing member 1007 is provided on the surface or internal of the sidewall of the body. In another embodiment of the present invention, the sensing member 1007 may be provided at other position on the body. FIG. 2 illustrates an exploded diagram of a structure of a mobile phone according to another embodiment of the present invention. As illustrated in FIG. 2, the sensing member 1007 is provided on the surface or internal of a part of the body covered by a main cover body of the battery cover, and the position is represented as B in FIG. 2. When the battery cover is in the closed state, the sensing member at position B faces the main cover body of the battery cover and spaced apart from the battery cover for a predetermined distance. When the sensing member 1007 is embedded in the body 1001 at position B, it is invisible to the user. In that case, the housing covering the sensing member 1007 separates the sensing member 1007 from the battery cover 1003. When the battery is cover is in the closed state, the capacitance sensor 1009 will sense the capacitance between the sensing member and the battery cover by means of the sensing member 1007. When the battery cover is removed, the capacitance sensor can sense the sharp decrease of the capacitance between the sensing member and the battery cover, and determine that the battery cover is removed. When being provided at position B on the surface of the body, the sensing member 1007 is configured not to contact the battery cover when the battery cover is closed, and to be spaced apart from the battery cover via air for a predetermined distance, at that time, the air serves as a medium between the sensing member and the battery cover. Alternatively, a medium layer may be provided on the surface of the sensing member 1007 to serve as the medium between the sensing member and the battery cover.

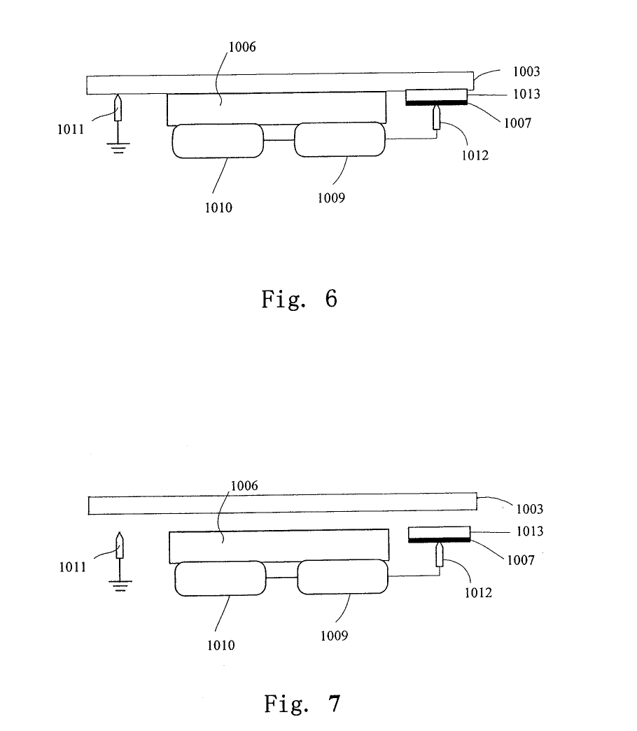

FIG. 6 illustrates a schematic diagram of a metal battery cover sensing circuit when the sensing member 1007 is provided at position B as illustrated in FIG. 2 according to another embodiment of the present invention. As illustrated in FIG. 6, the metal battery cover 1003 is grounded via a grounding structure 1011. The sensing member 1007 is provided at a position on the surface or internal of the body and faces the main cover body of the battery cover, and is spaced apart from the main cover body of the battery cover via the housing covering the sensing member 1007 or the medium 1013. When the battery cover 1003 is closed, the main cover body of the battery cover overlaps with the medium 1013 or the housing covering the sensing member. The capacitance sensor 1009 is connected to the sensing member 1007 via a contact 1012 (e.g., pogo pins or spring fingers, or wiring disposed inside the housing). The write control unit 1010 may be connected to the capacitance sensor 1009 directly or indirectly, so as to prohibit or allow data to be written into the pluggable memory card according to the sensing result of the capacitance sensor. When the metal battery cover is closed, the main cover body of the battery cover is very close to the sensing member 1007 (they are only separated by the housing covering the sensing member or the medium), and at that time, the capacitance sensor can sense a large capacitance from the sensing member 1007. When the metal battery cover is removed for a certain distance, as illustrated in FIG. 7, since the distance between the battery cover and the sensing member is increased, the capacitance is sensed by the capacitance sensor from the sensing member is obviously decreased and gets smaller than a certain predetermined threshold, thus it can be determined that the battery cover is removed.

FIGS. 6-7 are only used to explain the principle for implementing an embodiment of the present invention, instead of limiting the shapes and positions of the illustrated components. In the actual design, the capacitance sensor 1009 and the write control unit 1010 may be not under the battery, but at any other appropriate position in the mobile phone body. The write control unit 1010 also may be integrated into the CPU of the mobile phone.

In another embodiment of the present invention, preferably the mobile phone body or surface is provided with two or more sensing members, e.g., position A as illustrated in FIG. 1 and position B as illustrated in FIG. 2 are both provided with sensing members, so as to sense the capacitances between the sensing members at the two positions and the battery cover, and determine whether the battery cover is removed according to the sensed capacitance or a variation thereof. In case two or more positions of the body are provided with the sensing members, the influence of the user's hand on the sensed capacitance when the user's hand approaches or goes away from the mobile phone can be weakened, and then the wrong sensing of the state of the battery cover can be reduced.

The positions of the sensing members as illustrated in FIGS. 1-2 are just exemplary, and the arrangement of the sensing members is not limited thereto, e.g., the sensing members may be provided at other positions that enable a sensitive sensing of the capacitance variation caused by the battery cover.

In an embodiment of the present invention, the write control unit 1010 can acquire the sensed capacitance from the capacitance sensor 1009 periodically (e.g., at an interval of 0.1 s, 0.5 s, 1 s, etc., which are just exemplary and other values are possible), determine whether the battery cover is removed according to the sensed capacitance, and accordingly control (prohibit or allow) the writing of data such as a program into the memory card.

In another embodiment of the present invention, the write control unit 1010 may acquire the sensed capacitance from the capacitance sensor 1009 only when data (e.g., program, application or other data) is to be written into the memory card, then determine whether the battery cover is removed according to the sensed capacitance, and prohibit (including stopping) the data being written into the memory card when it is determined that the battery cover is removed.

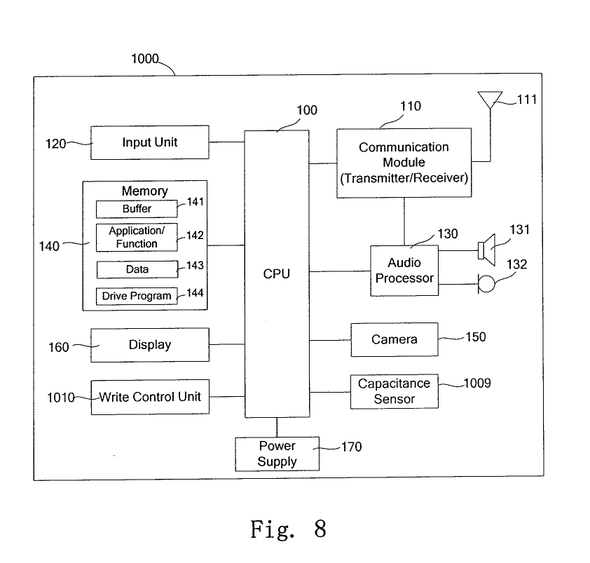

FIG. 8 is a schematic block diagram of a system structure of a mobile phone 1000 according to an embodiment of the present invention, including the aforementioned capacitance sensor 1009 and write control unit 1010. The drawing is exemplary, and other type of structure may be adopted to supplement or replace the structure, so as to realize the telecom function or other functions. As illustrated in FIG. 8, the mobile phone 1000 includes a CPU 100, a communication module 110, an input unit 120, an audio processing unit 130, a memory 140, a camera 150, a display 160, a power supply 170, a capacitance sensor 1009 and a write control unit 1010. The write control unit 1010 may be connected to the capacitance sensor 1009 directly, or via the CPU 100 as illustrated in FIG. 8. The write control unit 1010 may be integrated into the CPU 100. The CPU 100 (sometimes called as controller or operation control, including microprocessor or other processor device and/or logic device) receives an input and controls respective parts and operations of the mobile phone 1000. The input unit 120 provides the input to the CPU 100. The input unit 120 for example is a keyboard or a touch input device. The camera 150 captures image data and supplies data to the CPU 100 for a conventional usage, such as storage, transmission, etc.

The power supply 170 supplies electric power to the mobile phone 1000. The display 160 displays objects to be displayed such as images and characters. The display for example may be, but not limited to, an LCD display.

The memory 140 is coupled to the CPU 100. The memory 140 for example may be a solid state memory, such as Read Only Memory (ROM), Random Access Memory (RAM), SIM card, etc. The memory 140 also may be a memory which can store information even if the power is off and can be selectively erased and provided with more data, and the example of such a memory is sometimes called as EPROM, etc. The memory 140 also may be other device of a certain type. The memory 140 includes a is buffer memory 141 (sometimes called as buffer). The memory 140 may include an application/function storage section 142 that stores application program and function program or performs the operation procedure of the mobile phone 1000 via the CPU 100. The memory 140 may further include a data storage section 143 that stores data such as contact information, digital data, picture, sound and/or any other data used by the mobile phone 1000. A drive program storage section 144 of the memory 140 may include various drive programs of the mobile phone 1000 for performing the communication function and/or other functions (e.g., message transfer application, address list application, etc.) of the mobile phone 1000.

The communication module 110 is a transmitter/receiver 110 that transmits and receives a signal via an antenna 111. The communication module (transmitter/receiver) 110 is coupled to the CPU 100 to provide an input signal and receive an output signal, which may be the same as the situation of a conventional mobile phone. Based on different communication technologies, a same mobile phone may be provided with a plurality of communication modules 110, such as cellular network module, Bluetooth module and/or WLAN module, etc. The communication module (transmitter/receiver) 110 is further coupled to a loudspeaker 131 and a microphone 132 via an audio processor 130 to provide an audio output via the loudspeaker 131, and receive an audio input from the microphone 132, so as to realize the conventional telecom functions. The audio processor 130 may include any appropriate buffer, decoder, amplifier, etc. In addition, the audio processor 130 is coupled to the CPU 100, so that a sound may be recorded in the mobile phone through the microphone 132, and the sound stored in the mobile phone can be played through the loudspeaker 131.

In the aforementioned embodiments, the battery cover is a metal battery cover entirely made of metal or alloy. In another embodiment of the present invention, the battery cover may be partially made of the conductive material, and other parts thereof may be made of non-conductive material (e.g., plastics). The part of the battery cover made of the conductive material may be grounded by a grounding structure connected to the circuit mainboard.

In case the battery cover is partially made of the conductive material, the sensing is member still can be provided on the surface or internal of the body, and the only difference is that the sensing member is designed to be opposite to the main cover body of the battery cover and/or the conductive part on the sidewall of the battery cover and spaced apart from the battery cover for a predetermined distance, when the battery cover is in the closed state. As an example, the sensing member still can be provided at position A in FIG. 1 and/or position B in FIG. 2 on the condition that the part of the battery cover corresponding to position A and/or position B is made of conductive material and preferably grounded.

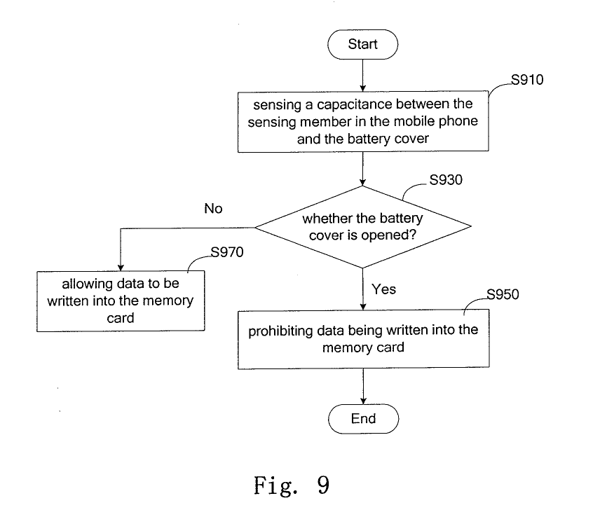

The method of writing protection for the memory card according to the embodiment of the present invention is described as follows in conjunction with the above mobile phone structure. As illustrated in FIG. 9, the writing protection of the memory card can be realized in the following steps.

A capacitance sensing step S910: sensing a capacitance between the sensing member in the mobile phone and the battery cover by using the capacitance sensor. In detail, this step senses the capacitance between the sensing member in the mobile phone and the conductive part of the battery cover by using the capacitance sensor. The sensing member for example may be, but not limited to, metal sheets or metal blocks of various shapes, and may be provided in the mobile phone in the manners as described in the above embodiments.

A determining step S930: determining whether the battery cover is removed according to the capacitance sensed in step S910. In detail, the determining step S930 determines that the battery cover is removed when the capacitance sensed in step S910 is smaller than a predetermined threshold; or determines that the battery cover is removed when a decrement of the capacitance sensed in step S910 in relation to the previously sensed capacitance is larger than a predetermined threshold. A writing protection step S950: prohibiting data being written into the pluggable memory card when step S930 determines that the battery cover is removed.

The method may further include: step S970, allowing data to be written into the memory card when the determining step S930 determines that the battery cover is not removed from the body.

The method of the present invention is not limited to be executed according to the time order as described herein, and can be executed sequentially, concurrently or independently in other time order. Thus, the execution order of the method as described herein does not constitute a limitation to the technical scope of the present invention.

The above descriptions and drawings illustrate various different features of the present invention. It shall be appreciated that a person skilled in the art can implement the above described and illustrated steps and processes by compiling appropriate computer codes.

The embodiments of the present invention are disclosed herein. A person skilled in the art will easily realize that the present invention has other applications under other environments. In fact, many other embodiments and implementations are also existed. The accompanied claims do not intend to limit the scope of the present invention as the above embodiments.

Features described and/or illustrated with respect to one embodiment can be used in one or more other embodiments in a same or similar way, and/or combine with or replace features in other embodiments.

It shall be appreciated that multiple parts of the embodiments of the present invention can be implemented via hardware, software, firmware or a combination thereof. In the above embodiments, multiple steps or methods can be implemented through software or firmware stored in a memory and executable by an appropriate instruction execution system. For example, if the implementation is made through hardware, e.g., in alternate embodiments, the implementation may be made by combining any one or a combination of the following prior arts: discrete logic circuit having logic gate circuit for implementing logic function for digital signal, application specific integrated circuit (ASIC) having appropriate combined logic gate circuit, programmable gate array (PGA), Field Programmable Gate Array (FPGA), etc.

When all or a part of the steps in the above method are implemented by instructing relevant hardware through a program, the program may be stored in a computer readable storage medium, such as ROM/RAM, magnetic disk, optical disk, etc.

Any process or method description or block described in the flowchart or in other way can be understood as including one or more modules, segments or portions for implementing codes of executable instructions in steps of specific logic function or process, and the range of the preferred embodiments further include other implementations, wherein the functions may be executed other than the order illustrated or discussed, including a substantially simultaneous manner based on concerned function or an inverse order, and this shall be appreciated by a person skilled in the art.

The above embodiments make further and detailed descriptions of the object, technical solution and beneficial effect of the present invention. It shall be appreciated that, the above descriptions are just embodiments of the present invention, and do not limit the protection scope of the present invention. Any amendment, equivalent substitution, improvement, etc. made within the spirit and principle of the present invention shall be covered by the protection scope of the present invention.

What is claimed is:

1. A mobile terminal comprising a body, a battery and a battery cover, wherein,
at least a part of the battery cover is made of conductive material;
the body comprising:
a memory card socket configured to accommodate a pluggable memory card;
at least one sensing member provided on a surface or internal of the body and spaced apart from the battery cover, and configured to face the part made of conductive material when the battery cover is in a closed state;
a capacitance sensor connected to the at least one sensing member and configured to sense capacitance between the sensing member and the battery cover; and
a write control unit configured to determine whether the battery cover is removed according to the capacitance sensed by the capacitance sensor, and prohibit data being written into the memory card when it is determined that the battery cover is removed.

2. The mobile terminal according to claim 1, wherein,
the write control unit is configured to determine that the battery cover is removed when the capacitance currently sensed by the capacitance sensor is smaller than a predetermined threshold; or
the write control unit is configured to determine that the battery cover is removed when a decrement of the capacitance currently sensed by the capacitance sensor in relation to a previously sensed capacitance is larger than a predetermined threshold.

3. The mobile terminal according to claim 1, wherein the write control unit is further configured to allow data to be written into the memory card when it is determined that the battery cover is not removed.

4. The mobile terminal according to claim 1, wherein the sensing member is a metal sheet formed on the surface or internal of the body through metal insert molding.

5. The mobile terminal according to claim 1, wherein the at least one sensing member is spaced apart from the battery cover via air or a medium layer coated on a surface of the at least one sensing member, when the at least one sensing member is provided on the surface of the body.

6. The mobile terminal according to claim 1, wherein the part made of conductive material is grounded.

7. A method of writing protection for a memory card in a mobile terminal, wherein the method comprising:
a capacitance sensing step: sensing capacitance between a sensing member provided in the mobile terminal and a conductive part of a battery cover of the mobile terminal;
a determining step: determining whether the battery cover is removed according to the capacitance sensed in the capacitance sensing step; and
a writing protection step: prohibiting data being written into a pluggable memory card of the mobile terminal when the determining step determines that the battery cover is removed.

8. The method according to claim 7, wherein the writing protection step further comprising:
allowing data to be written into the memory card when the determining step determines that the battery cover is not removed from the mobile terminal.

9. The method according to claim 7, wherein in the determining step,
determining that the battery cover is removed when the capacitance currently sensed in the capacitance sensing step is smaller than a predetermined threshold; or
determining that the battery cover is removed when a decrement of the capacitance currently sensed in the capacitance sensing step in relation to a previously sensed capacitance is larger than a predetermined threshold.
